(19) United States
(12) Patent Application Publication
(10) Pub. No.: US 2026/0086164 A1
(43) Pub. Date: Mar. 26, 2026

(54) ELECTROCHEMICAL IMPEDANCE SPECTROSCOPY MEASUREMENT APPARATUS AND METHOD, AND BATTERY SYSTEM

(71) Applicant: SK ON CO., LTD., Seoul (KR)

(72) Inventors: Kyu Min HWANG, Daejeon (KR); Sol San SON, Daejeon (KR); Jae Hee LEE, Daejeon (KR); Hyun Jun LEE, Daejeon (KR); Ung JON, Daejeon (KR)

(21) Appl. No.: 19/333,367

(22) Filed: Sep. 19, 2025

(30) Foreign Application Priority Data
Sep. 25, 2024 (KR) 10-2024-0129898

(51) Int. Cl. G01R 31/389; G01R 31/396

(52) U.S. Cl. CPC G01R 31/389; G01R 31/396

(57) ABSTRACT

An electrochemical impedance spectroscopy measurement apparatus, method, and a battery system are provided. The method and the battery system use the apparatus. The electrochemical impedance spectroscopy measurement apparatus includes an EIS measurement part, and an AC discharge switching part. The EIS measurement part is connected to each of a plurality of battery cells included in a battery module, and is configured to perform electrochemical impedance spectroscopy (EIS) measurement on each of the plurality of battery cells during AC discharge of the battery module. The AC discharge switching part is connected to the battery module to form an AC discharge path so that AC discharge of the battery module is performed for electrochemical impedance spectroscopy (EIS) measurement in the EIS measurement part. The AC discharge path is connected to a node with the highest voltage among a plurality of nodes of the plurality of battery cells electrically connected.

### CROSS REFERENCE TO RELATED APPLICATION

The present application claims priority to Korean Patent Application No. 10-2024-0129898, filed Sep. 25, 2024, the entire contents of which are incorporated herein for all purposes by this reference.

### TECHNICAL FIELD

The embodiments of the present disclosure relate generally to battery technology and more specifically to an electrochemical impedance spectroscopy measurement apparatus and method for a battery, and to a battery system employing the electrochemical impedance spectroscopy measurement apparatus.

### BACKGROUND

An electric vehicle refers to a vehicle that operates using electricity, and is equipped with a battery that supplies the electricity. The battery is used as a power source for driving an electric motor for propulsion of the vehicle.

The electric vehicle is connected to a charger for charging the battery, and the battery is charged by the power supplied from the charger to the electric vehicle.

In such electric vehicles, a battery management system (BMS) is also mounted and used to diagnose and control charging and discharging states of the battery to increase the efficiency of the battery and maximize its service life.

In recent years, impedance measurement with electrochemical impedance spectroscopy (EIS) has been used to diagnose the state of the battery, and a great deal of research has been conducted on methods capable of diagnosing battery defects using electrochemical impedance spectroscopy. EIS enables non-invasive, real-time monitoring of internal battery parameters such as resistance and capacitance, which are indicative of aging, degradation, or failure modes.

However, many challenges remain that require new solutions. In view of the foregoing, the embodiments of the present disclosure aim to provide an improved an electrochemical impedance spectroscopy measurement apparatus and method that is particularly advantageous for a battery.

### SUMMARY

Embodiments of the present disclosure provide an electrochemical impedance spectroscopy measurement apparatus and method, and a battery system that are capable of performing electrochemical impedance spectroscopy (EIS) measurement for a battery.

Embodiments of the present disclosure provide an electrochemical impedance spectroscopy measurement apparatus and method, and a battery system that are capable of continuously forming an AC discharge path even if a connection line for an AC discharge path connected to a battery is disconnected during electrochemical impedance spectroscopy (EIS) measurement for the battery through AC discharge.

An electrochemical impedance spectroscopy measurement apparatus and method, and a battery system according to embodiments of the present disclosure may be widely applicable to electric vehicles, battery charging stations, and other green technology fields such as solar power generation and wind power generation using batteries.

An electrochemical impedance spectroscopy measurement apparatus and method, and a battery system according to embodiments of the present disclosure are applicable to eco-friendly electric vehicles or hybrid vehicles to curb air pollution and greenhouse gas emission and to prevent climate change.

According to an embodiment of the present disclosure, there is an electrochemical impedance spectroscopy measurement apparatus including an EIS measurement part connected to each of a plurality of battery cells included in a battery module, and configured to perform electrochemical impedance spectroscopy (EIS) measurement on each of the plurality of battery cells during AC discharge of the battery module; and an AC discharge switching part connected to the battery module to form an AC discharge path so that AC discharge of the battery module is performed for electrochemical impedance spectroscopy (EIS) measurement in the EIS measurement part, wherein the AC discharge path is connected to a node with the highest voltage among a plurality of nodes of the plurality of battery cells electrically connected.

According to an embodiment of the present disclosure, the AC discharge switching part may include an AC generation switching part electrically connected to the battery module including the plurality of battery cells, and including a first switching element for generating AC; one or more power consumption distribution parts connected in series to the AC generation switching part; a switching control part configured to control an on/off operation of the AC generation switching part according to a determined frequency for electrochemical impedance spectroscopy (EIS) measurement; and a discharge path formation part positioned between, connecting the battery module and the power consumption distribution parts and configured to form the AC discharge path.

According to an embodiment, the discharge path formation part may include a main discharge path part connected to the node with the highest voltage among the plurality of nodes of the plurality of battery cells; and one or more sub-discharge path parts connected to the remaining nodes excluding the node with the highest voltage among the plurality of nodes of the plurality of battery cells.

According to an embodiment, the main discharge path part may include a first fuse and a first diode connected in series, and the sub-discharge path part may include a second fuse and a second diode connected in series.

According to an embodiment, the power consumption distribution part may include a second switching element of which a drain terminal is connected in series to an output terminal of the discharge path formation part; a resistance element of which one end is connected to one of the plurality of battery cells and of which the other end is connected to a gate terminal of the second switching element; and a semiconductor device of which an input terminal is connected to a source terminal of the second switching element and of which an output terminal is connected to the gate terminal of the second switching element, and configured to induce a constant voltage output, and the power consumption distribution part is configured to maintain the second switching element continuously in a turned-on state by causing a voltage at the gate terminal of the second switching element to be maintained higher than a voltage at the source terminal and as high as a breakdown voltage of the semiconductor device.

According to an embodiment, the second switching element may be a field effect transistor, and the semiconductor device may be a Zener diode.

According to an embodiment, the AC discharge switching part may further include a sensing resistor part positioned between, connecting the AC generation switching part and the battery module including the plurality of battery cells, and the switching control part may be configured to control an on/off cycle of the AC generation switching part by measuring a voltage applied to the sensing resistor part to maintain a determined AC frequency for electrochemical impedance spectroscopy (EIS) measurement.

According to an embodiment, the sensing resistor part may include one or more resistance elements.

According to an embodiment, the EIS measurement part may be connected to a measurement path protection fuse for protecting an electrochemical impedance spectroscopy (EIS) measurement path at each connection to the nodes of the plurality of battery cells included in the battery module.

According to an embodiment of the present disclosure, there is an electrochemical impedance spectroscopy measurement apparatus including an electrochemical impedance spectroscopy (EIS) measurement part connected to battery cells of a battery module for making an EIS measurement on the battery module during AC discharge of the battery module; and an AC discharge switching part connected to the battery module configured to form an AC discharge path connected to a node with the highest voltage in the battery module, wherein the AC discharge switching part comprises: a main discharge path part connected to the node with the highest voltage; and one or more sub-discharge path parts connected to remaining nodes of the battery cells, and wherein the main discharge path part comprises a first fuse and a first diode connected in series.

According to an embodiment of the present disclosure, there is provided an electrochemical impedance spectroscopy measurement method including generating, by an AC discharge switching part connected to a battery module including a plurality of battery cells, AC corresponding to a frequency for electrochemical impedance spectroscopy (EIS) measurement for the battery module; performing, by an EIS measurement part connected to a plurality of nodes of the plurality of battery cells included in the battery module, electrochemical impedance spectroscopy (EIS) measurement on each of the plurality of battery cells included in the battery module; and responding to, when one of a plurality of discharge path formation parts connected to the plurality of nodes of the plurality of battery cells electrically connected is disconnected during electrochemical impedance spectroscopy (EIS) measurement of the plurality of battery cells, disconnection by forming an AC discharge path through one of the remaining discharge path formation parts.

According to an embodiment, in the operation of responding to the disconnection of the AC discharge path, when the discharge path formation part connected to a node with the highest voltage among the plurality of nodes of the plurality of battery cells is disconnected, the AC discharge path may be formed through the discharge path formation part connected to a node with the highest voltage among the remaining plurality of discharge path formation parts.

According to an embodiment, in the operation of responding to the disconnection of the AC discharge path, when one of the plurality of discharge path formation parts connected to the remaining plurality of nodes excluding a node with the highest voltage among the plurality of nodes of the plurality of battery cells is disconnected, the AC discharge path formed through the discharge path formation part connected to the node with the highest voltage may be maintained.

According to an embodiment of the present disclosure, there is provided a battery system including a battery module including a plurality of battery cells; an EIS measurement device connected to each of the plurality of battery cells included in the battery module, and configured to perform electrochemical impedance spectroscopy (EIS) measurement on each of the plurality of battery cells during AC discharge of the battery module; and an AC discharge switching device connected to the battery module to form an AC discharge path so that AC discharge of the battery module is performed for electrochemical impedance spectroscopy (EIS) measurement in the EIS measurement device, wherein the AC discharge path is connected to a node with the highest voltage among a plurality of nodes of the plurality of battery cells.

According to an embodiment, the AC discharge switching device may further include an AC generation switching part electrically connected to the battery module including the plurality of battery cells, and including a first switching element for generating AC; one or more power consumption distribution parts connected in series to the AC generation switching part; a switching control part configured to control an on/off operation of the AC generation switching part according to a determined frequency for electrochemical impedance spectroscopy (EIS) measurement; a discharge path formation part positioned between, connecting the battery module and the power consumption distribution parts and configured to form the AC discharge path; and a sensing resistor part positioned between, connecting the AC generation switching part and the battery module including the plurality of battery cells, and the switching control part is configured to control an on/off cycle of the AC generation switching part by measuring a voltage applied to the sensing resistor part to maintain a determined AC frequency for electrochemical impedance spectroscopy (EIS) measurement.

The features and advantages of the embodiments of the present disclosure will be more clearly understood from the following detailed description based on the accompanying drawings.

The terms and words used in the present specification and claims should not be interpreted as being limited to typical meanings and dictionary definitions, but should be interpreted as having meanings and concepts relevant to the technical scope of the present disclosure based on the rule according to which an inventor can appropriately define the concept of the term to describe most appropriately the best method he or she knows for carrying out the present disclosure.

According to an embodiment of the present disclosure, electrochemical impedance spectroscopy (EIS) measurement for the battery can be performed.

According to an embodiment of the present disclosure, even when a particular connection line for AC discharge connected to the battery is disconnected and AC discharge is hindered during electrochemical impedance spectroscopy (EIS) measurement for the battery through AC discharge, the AC discharge path can be continuously formed and electrochemical impedance spectroscopy (EIS) measurement for the battery can be continuously performed.

According to an embodiment of the present disclosure, the situation in which electrochemical impedance spectroscopy (EIS) measurement becomes impossible due to external factors such as disconnection can be prevented by multiplying (redundancy) the AC discharge path.

According to an embodiment of the present disclosure, the durability and stability of the AC discharge switching part for AC discharge can be improved.

### BRIEF DESCRIPTION OF THE DRAWINGS

The above and other objectives, features, and other advantages of the embodiments of the present disclosure will be more clearly understood from the following detailed description when taken in conjunction with the accompanying drawings, in which:

FIG. 1 is a diagram illustrating an electrochemical impedance spectroscopy measurement apparatus according to an embodiment of the present disclosure;

FIG. 2 is a diagram illustrating a circuit configuration of an AC discharge switching part in an electrochemical impedance spectroscopy measurement apparatus according to an embodiment of the present disclosure;

FIG. 3 is a diagram illustrating an AC discharge switching part further including a sensing resistor part in an electrochemical impedance spectroscopy measurement apparatus according to an embodiment of the present disclosure;

FIG. 4 is a diagram illustrating an operation of forming an AC discharge path in the event of disconnection of a main discharge path part in an electrochemical impedance spectroscopy measurement apparatus according to an embodiment of the present disclosure;

FIG. 5 is a diagram illustrating an operation of forming an AC discharge path in the event of disconnection of a sub-discharge path part in an electrochemical impedance spectroscopy measurement apparatus according to an embodiment of the present disclosure;

FIG. 6 is a flowchart illustrating each operation of an electrochemical impedance spectroscopy measurement method according to an embodiment of the present disclosure;

FIG. 7 is a diagram illustrating an operation of responding to disconnection of an AC discharge path in an electrochemical impedance spectroscopy measurement method according to an embodiment of the present disclosure; and

FIG. 8 is a configuration diagram illustrating a battery system according to an embodiment of the present disclosure.

### DETAILED DESCRIPTION

Hereinafter, the embodiments of the present disclosure will be described in detail (with reference to the accompanying drawings). However, this is merely illustrative and the embodiments are not limited to the specific embodiments described.

It should be understood that the drawings are intended to illustrate embodiments of the present disclosure and may be schematics which may include one or more features being exaggerated for clarity and ease of understanding.

As used herein, the terms “have”, “may have”, “include”, or “may include” a feature (e.g., a number, function, operation, or an element such as a component) indicate the existence of the feature and do not exclude the existence of other features.

Hereinafter, embodiments of the present disclosure will be described in detail with reference to the accompanying drawings.

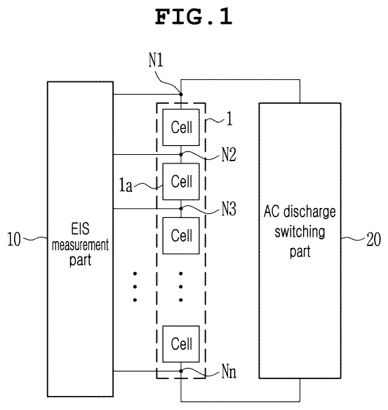

FIG. 1 is a diagram illustrating an electrochemical impedance spectroscopy measurement apparatus according to an embodiment of the present disclosure.

Referring to FIG. 1, the electrochemical impedance spectroscopy measurement apparatus according to an embodiment of the present disclosure may include an EIS measurement part 10 connected to each of a plurality of battery cells la included in a battery module 1, and configured to perform electrochemical impedance spectroscopy (EIS) measurement on each of the plurality of battery cells la during AC discharge of the battery module 1. The electrochemical impedance spectroscopy measurement apparatus further includes an AC discharge switching part 20 connected to the battery module 1 to form an AC discharge path so that AC discharge of the battery module 1 is performed for electrochemical impedance spectroscopy (EIS) measurement in the EIS measurement part 10, wherein the AC discharge path is connected to a node with the highest voltage among nodes of the plurality of battery cells la electrically connected.

In the battery module 1, the plurality of battery cells la may be electrically connected. In the battery module 1, the plurality of battery cells la may be connected in series, connected in parallel, or connected in a combination of series and parallel.

The EIS measurement part 10 may be connected to the battery module 1 and may perform electrochemical impedance spectroscopy (EIS) measurement to diagnose the state of the battery module 1. The EIS measurement part 10 may be connected to the nodes (N1 to Nn) of the plurality of battery cells 1a included in the battery module 1 and may perform electrochemical impedance spectroscopy (EIS) measurement on each battery cell 1a. The nodes (N1 to Nn) of the plurality of battery cells la may be connection lines that make connections between the battery cells 1a.

Electrochemical impedance spectroscopy (EIS) is a technology for diagnosing a battery by measuring the sum of components that appear when alternating current or voltage is applied, that is, the impedance. Electrochemical impedance spectroscopy (EIS) may diagnose manufacturing defects, internal short circuits, overcharging, overdischarging, or remaining capacity of the battery. Electrochemical impedance spectroscopy (EIS) can reduce inspection time and lower costs compared to conventional battery inspection methods.

The AC discharge switching part 20 may perform AC discharge based on the battery module 1 so that the EIS measurement part 10 can perform impedance measurement with electrochemical impedance spectroscopy (EIS) on each of the plurality of battery cells la included in the battery module 1. In this case, the discharged AC may be perturbation current.

The AC discharge switching part 20 may be electrically connected to the battery module 1, which includes the plurality of battery cells la, to form the AC discharge path. The AC discharge path may include a plurality of discharge path formation parts connected to the nodes (N1 to Nn) of the plurality of battery cells la. The AC discharge switching part 20 may be connected to the node with the highest voltage among the nodes (N1 to Nn) of the plurality of battery cells la through the plurality of discharge path formation parts, and may perform AC discharge based on the battery module 1. The node with the highest voltage among the nodes (N1 to Nn) of the plurality of battery cells la may be determined based on the negative terminal (IN) of the battery module 1.

Through this, the AC discharge switching part 20 may form the AC discharge path to perform AC discharge based on the battery module 1, and the EIS measurement part 10 may perform electrochemical impedance spectroscopy (EIS) measurement on each battery cell 1a.

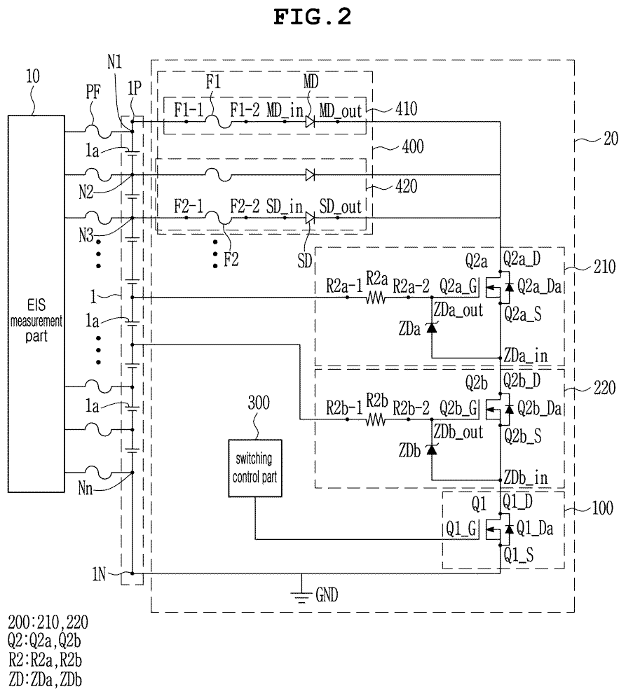

FIG. 2 is a diagram illustrating a circuit configuration of an AC discharge switching part in an electrochemical impedance spectroscopy measurement apparatus according to an embodiment of the present disclosure.

Referring to FIG. 2, in the electrochemical impedance spectroscopy measurement apparatus according to an embodiment of the present disclosure, the AC discharge switching part 20 may include an AC generation switching part 100 electrically connected to the battery module 1 including the plurality of battery cells 1a and including a first switching element (Q1) for generating AC; one or more power consumption distribution parts 200 connected in series to the AC generation switching part 100; a switching control part 300 configured to control an on/off operation of the AC generation switching part 100 according to a determined frequency for electrochemical impedance spectroscopy (EIS) measurement; and a discharge path formation part 400 positioned between the battery module 1 and the power consumption distribution parts 200 for connecting the battery module 1 and the power consumption distribution parts 200 and configured to form an AC discharge path.

The discharge path formation part 400 may include a main discharge path part 410 connected to the node with the highest voltage among the plurality of nodes (N1 to Nn) of the plurality of battery cells 1a; and one or more sub-discharge path parts 420 connected to the remaining nodes excluding the node with the highest voltage among the plurality of nodes (N1 to Nn) of the plurality of battery cells 1a.

The main discharge path part 410 may include a first fuse (F1) and a first diode (MD) connected in series. The sub-discharge path part 420 may include a second fuse (F2) and a second diode (SD) connected in series.

The first diode (MD) of the main discharge path part 410 and the second diode (SD) of the sub-discharge path part 420 may each allow current to flow in one direction. The first fuse (F1) of the main discharge path part 410 and the second fuse (F2) of the sub-discharge path part 420 may each break in the event of overcurrent to protect the AC discharge switching part 20.

The first diode (MD) of the main discharge path part 410 may be connected to the node with the highest voltage among the plurality of nodes (N1 to Nn) of the plurality of battery cells 1a to form the main discharge path. For example, referring to FIG. 2, the first diode (MD) may be connected to node N1 among the plurality of nodes (N1 to Nn) of the plurality of battery cells 1a. That is, among the nodes (N1 to Nn) of the plurality of battery cells 1a, node N1 may be the node with the highest voltage based on the negative terminal (IN) of the battery module 1.

One or more second diodes (SDs) of the sub-discharge path parts 420 may be provided, and may be connected to the remaining nodes excluding the node with the highest voltage among the plurality of nodes (N1 to Nn) of the plurality of battery cells 1a to form a sub-discharge path. For example, referring to FIG. 2, the second diodes may be respectively connected to the remaining nodes (N2 and N3) excluding the node (N1) with the highest voltage among the plurality of nodes (N1 to Nn) of the plurality of battery cells 1a.

When the connection between the node N1 of the battery cell 1a and the first diode (MD) of the main discharge path part 410 is disconnected, the sub-discharge path part 420 may form the sub-discharge path by connecting to anode with the highest voltage among the remaining nodes (N2 and N3) excluding the node (N1) with the highest voltage.

Referring to FIG. 2, one end (F1-1) of the first fuse (F1) of the main discharge path part 410 may be connected to node N1 among the plurality of nodes (N1 to Nn) of the plurality of battery cells 1a, and the other end (F1-2) of the first fuse (F1) may be connected to the input terminal (MD_in) of the first diode (MD). The output terminal (MD_out) of the first diode (MD) may be connected to the power consumption distribution part 200, specifically, a second switching element (Q2)

One ends (F2-1) of the second fuses (F2) of the sub-discharge path parts 420 may be respectively connected to nodes N2 and N3 among the plurality of nodes (N1 to Nn) of the plurality of battery cells 1a, and the other ends (F2-2) of the second fuses (F2) may be respectively connected to the input terminals (SD_in) of the second diodes (SDs) corresponding to each fuse. The output terminal (SD_out) of the second diode (SD) may be connected to the power consumption distribution part 200, specifically, the second switching element (Q2).

The output terminal (MD_out) of the first diode (MD) and the output terminals (SD_out) of the one or more second diodes (SD) may be connected to one common line and connected to the power consumption distribution part 200, specifically, the second switching element (Q2). The first diode (MID) of the main discharge path part 410 and the one or more second diodes (SDs) of the sub-discharge path parts 420 may each be connected in a forward direction.

Accordingly, the discharge path formation part 400 may form the main discharge path by being connected to the node with the highest voltage among the plurality of nodes (N1 to Nn) of the plurality of battery cells 1a through the main discharge path part 410. When the main discharge path is disconnected, the sub-discharge path may be formed through the sub-discharge path part 420.

As such, according to an embodiment of the present disclosure, in forming the AC discharge path, the AC discharge path is multiplexed into the main discharge path and the sub-discharge path is made. Therefore, even when any one of the connection lines connected to the plurality of nodes (N1 to Nn) of the plurality of battery cells la is disconnected, the AC discharge path is always formed. This can prevent a situation in which electrochemical impedance spectroscopy (EIS) measurement for the plurality of battery cells 1a becomes impossible in the EIS measurement part 10.

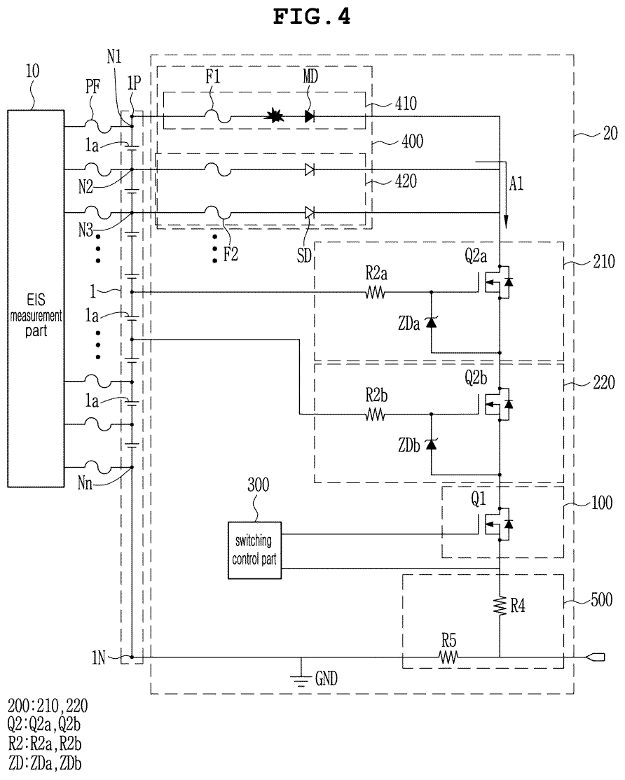

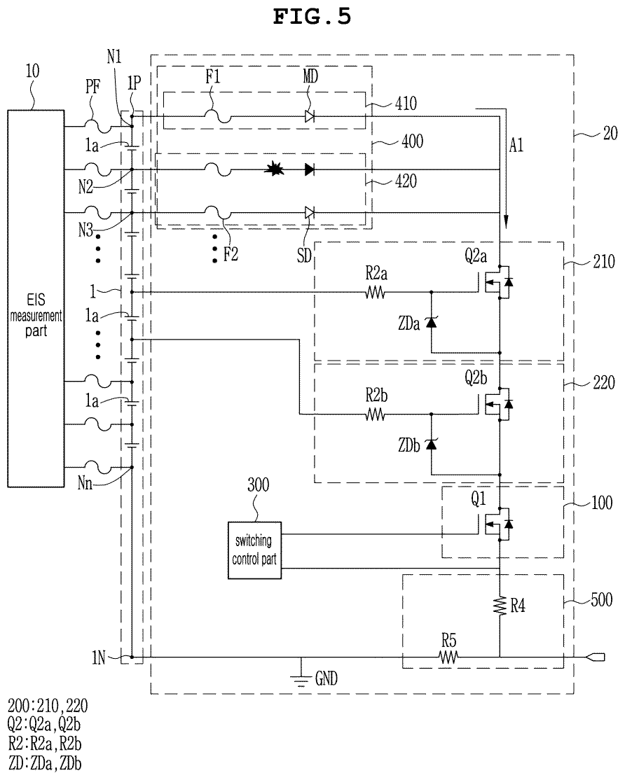

The response to the disconnection of the AC discharge path performed by the discharge path formation part 400 will be described in more detail later with reference to FIGS. 4 and 5.

In addition, the discharge path formation part 400 uses diodes connected in a forward direction to prevent the voltage of any of the nodes (N1 to Nn) of the plurality of battery cells 1a output through one common line from flowing back to the battery cells 1a through the other diodes connected to the same one common line.

Referring to FIG. 2, the AC generation switching part 100 may perform a switching operation to generate AC corresponding to the determined frequency for electrochemical impedance spectroscopy (EIS) measurement. The AC generation switching part 100 may include the first switching element (Q1), and the first switching element (Q1) may be a field effect transistor (FET). The source terminal (Q1_S) of the first switching element (Q1) may be connected in series to negative terminal (IN) of the battery module (1), the drain terminal (Q1_D) of the first switching element (Q1) may be connected to the power consumption distribution part 200, and the gate terminal (Q1_G) of the first switching element (Q1) may be connected to the switching control part 300.

The AC generation switching part 100 may further include a diode (Q1_Da) connected to the first switching element (Q1). The anode of the diode (Q1_Da) may be connected to the source terminal (Q1_S) of the first switching element (Q1), and the cathode of the diode (Q1_Da) may be connected to the drain terminal (Q1_D) of the first switching element (Q1).

The switching control part 300 may control the AC generation switching part 100, and the AC generation switching part 100 may be switched under the control of the switching control part 300. The AC generation switching part 100 may remain turned off so that no AC flows when the EIS measurement part 10 does not perform electrochemical impedance spectroscopy (EIS) measurement. The AC generation switching part 100 may be repeatedly switched on and off for AC generation when the EIS measurement part 10 performs electrochemical impedance spectroscopy (EIS) measurement. The AC generation switching part 100 may be pulse width modulation (PWM) controlled by the switching control part 300 for AC generation when the EIS measurement part 10 performs electrochemical impedance spectroscopy (EIS) measurement. The switching control part 300 may be realized together with the EIS measurement part 10 in a single EIS chip.

Referring to FIG. 2, one or more power consumption distribution parts 200 may be connected in series to the AC generation switching part 100. The power consumption distribution part 200 may distribute the power consumption generated when AC is discharged from the battery module 1 through the AC generation switching part 100. Herein, the power consumption (P) may be expressed as “module voltage (V)×perturbation current (I)”.

The power consumption distribution part 200 may be positioned between the discharge path formation part 400 and the AC generation switching part 100 for connecting the discharge path formation part 400 and the AC generation switching part 100.

The power consumption distribution part 200 may include the second switching element (Q2) of which the drain terminal is connected in series to the output terminal of the discharge path formation part 400, a resistance element (R2) of which one end is connected to one of the plurality of battery cells la and of which the other end is connected to the gate terminal of the second switching element (Q2), and a semiconductor device (ZD) of which the input terminal is connected to the source terminal of the second switching element (Q2) and of which the output terminal is connected to the gate terminal of the second switching element (Q2), and inducing a constant voltage output. The power consumption distribution part 200 causes the voltage at the gate terminal of the second switching element (Q2) to be an output higher than the voltage at the source terminal and equal to or higher than the breakdown voltage of the semiconductor device (ZD), so that the second switching element (Q2) is continuously maintained in a turned-on state. This way stable conduction through Q2 is achieved thus enabling uninterrupted operation of the sub-discharge path.

The second switching element (Q2) may be a field effect transistor, and the semiconductor device (ZD) may be a Zener diode.

One end of the resistance element (R2) may be connected to one of the plurality of nodes (N1 to Nn) of the plurality of battery cells la and the other end of the resistance element (R2) may be connected to the gate terminal of the second switching element (Q2).

Since the voltage applied from the battery module 1 to the first switching element (Q1) of the AC generation switching part 100 is large, a plurality of the power consumption distribution parts 200, rather than just one, may be formed for voltage distribution. In an embodiment of the present disclosure, two power consumption distribution parts are provided as shown in FIG. 2. However, the embodiments are not particularly limited to the number of the power consumption distribution parts.

Referring to FIG. 2, the power consumption distribution part 200 may include a first power consumption distribution part 210 and a second power consumption distribution part 220.

The first power consumption distribution part 210 may include a second-a switching element (Q2a) of which the drain terminal (Q2a_D) is connected in series to the output terminal of the discharge path formation part 400; a first resistance element (R2a) of which one end (R2a-1) is connected to one of the plurality of battery cells la and of which the other end (R2a-2) is connected to the gate terminal (Q2a_G) of the second-a switching element; and a first semiconductor device (ZDa) of which the input terminal (ZDa_in) is connected to the source terminal (Q2a_S) of the second-a switching element (Q2a) and of which the output terminal (ZDa_out) is connected to the gate terminal (Q2a_G) of the second-a switching element (Q2a), and including a constant voltage output. The first power consumption distribution part 210 causes the voltage at the gate terminal (Q2a_G) of the second-a switching element (Q2a) to be maintained higher than the voltage at the source terminal (Q2a_S) and to be equal to or higher than the breakdown voltage of the first semiconductor device (ZDa), so that the second-a switching element (Q2a) is continuously maintained in a turned-on state.

The output terminal of the discharge path formation part 400 may be one common line for the output terminal (MD_out) of the first diode (MID) of the main discharge path part 410 and the output terminals (SD_out) of the second diodes (SDs) of the one or more sub-discharge path parts 420.

The source terminal (Q2a_S) of the second-a switching element (Q2a) may be connected in series to the drain terminal (Q2b_D) of a second-b switching element (Q2b), and the drain terminal (Q2a_D) of the second-a switching element (Q2a) may be connected in series to the output terminal of the discharge path formation part 400, and the gate terminal (Q2a_G) of the second-a switching element (Q2a) may be connected to the first resistance element (R2a).

The first power consumption distribution part 210 may further include a second-a diode (Q2a_Da) connected to the second-a switching element (Q2a). The anode of the second-a diode (Q2a_Da) may be connected to the source terminal (Q2a_S) of the second-a switching element (Q2a), and the cathode of the second-a diode (Q2a_Da) may be connected to the drain terminal (Q2a_D) of the second-a switching element (Q2a).

One end (R2a-1) of the first resistance element (R2a) may be connected to one of the nodes (N1 to Nn) of the plurality of battery cells 1a, and the other end (R2a-2) of the first resistance element (R2a) may be connected to the gate terminal (Q2a_G) of the second-a switching element (Q2a).

The second power consumption distribution part 220 may include the second-b switching element (Q2b) of which the drain terminal Q2b_D) is connected in series to the source terminal(Q2a_S) of the second-a switching element (Q2a) of the first power consumption distribution part 210 and of which the source terminal (Q2b_S) is connected to in series to the drain terminal (Q1_D) of the first switching element (Q1) of the AC generation switching part 100; a second resistance element (R2b) of which one end (R2b-1) is connected to one of the plurality of battery cells 1a and of which the other end (R2b-2) is connected to the gate terminal (Q2b_G) of the second-b switching element (Q2b); and a second semiconductor device (ZDb) of which the input terminal (ZDb_in) is connected to the source terminal (Q2b_S) of the second-b switching element (Q2b) and of which the output terminal (ZDb_out) is connected to the gate terminal (Q2b_G) of the second-b switching element (Q2b), and inducing a constant voltage output. The second power consumption distribution part 220 causes the voltage at the gate terminal (Q2b_G) of the second-b switching element (Q2b) to be maintained higher than the voltage at the source terminal (Q2b_S) and as high as the breakdown voltage of the second semiconductor device (ZDb), so that the second-b switching element (Q2b) is continuously maintained in a turned-on state.

The source terminal (Q2b_S) of the second-b switching element (Q2b) may be connected in series to the drain terminal (Q1_D) of the first switching element (Q1) of the AC generation switching part 100. The drain terminal (Q2b_D) of the second-b switching element (Q2b) may be connected in series to the source terminal (Q2a_S) of the second-a switching element (Q2a), and the gate terminal (Q2a_G) of the second-b switching element (Q2b) may be connected to the second resistance element (R2b).

The second power consumption distribution part 220 may further include a second-b diode (Q2a_Db) connected to the second-b switching element (Q2b). The anode of the second-b diode (Q2a_Db) may be connected to the source terminal (Q2b_S) of the second-b switching element (Q2b), and the cathode of the second-b diode (Q2a_Db) may be connected to the drain terminal (Q2b_D) of the second-b switching element (Q2b).

One end (R2b-1) of the second resistance element (R2b) may be connected to one of the nodes (N1 to Nn) of the plurality of battery cells la, and the other end (R2b-2) of the second resistance element (R2b) may be connected to the gate terminal (Q2b_G) of the second-b switching element (Q2b).

The first resistance element (R2a) and the second resistance element (R2b) may be respectively connected to nodes of different battery cells 1a among the plurality of nodes (N1 to Nn) of the plurality of battery cells 1a, and may transfer the driving voltage for respective switching operations for the second-a switching element (Q2a) and the second-b switching element (Q2b) matched thereto.

Accordingly, the power consumption distribution part 200 distributes the voltage between the positive terminal (1P) and the negative terminal (1N) of the battery module 1 through the circuit configuration using the second switching element (Q2), which is a field effect transistor, the resistance element (R2), and the semiconductor device (ZD), which is a Zener diode, thereby reducing the impact of the withstand voltage stress on the first switching element (Q1) of the AC generation switching part 100 and managing heat generation.

In the meantime, the EIS measurement part 10 may be connected to a measurement path protection fuse (PF) for protecting an electrochemical impedance spectroscopy (EIS) measurement path at each connection to the nodes (N1 to Nn) of the plurality of battery cells 1a included in the battery module 1. The flow of overcurrent may be blocked.

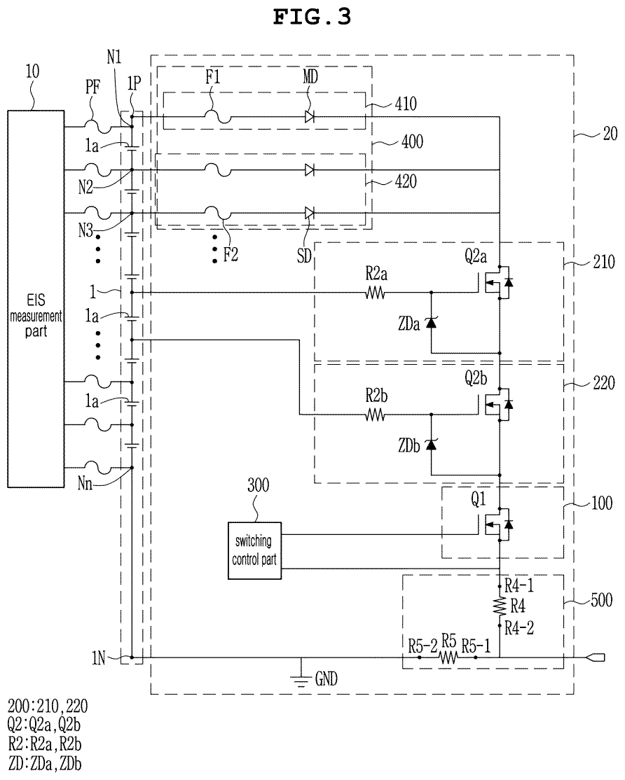

FIG. 3 is a diagram illustrating an AC discharge switching part further including a sensing resistor part in an electrochemical impedance spectroscopy measurement apparatus according to an embodiment of the present disclosure.

Referring to FIG. 3, in the electrochemical impedance spectroscopy measurement apparatus according to an embodiment of the present disclosure, the AC discharge switching part 20 may further include a sensing resistor part 500 positioned between and for electrically connecting the AC generation switching part 100 and the battery module 1 including the plurality of battery cells 1a. The switching control part 300 may measure the voltage applied to the sensing resistor part 500 and control the on/off cycle of the AC generation switching part 100 so that the determined AC frequency for electrochemical impedance spectroscopy (EIS) measurement is maintained. This configuration may further allow for current sensing across the discharge path, enabling accurate monitoring and control of battery behavior.

The sensing resistor part 500 may include one or more resistance elements to identify AC flowing for electrochemical impedance spectroscopy (EIS) measurement in the form of a voltage. Referring to FIG. 3, the sensing resistor part 500 may connect two resistance elements (R4 and R5) in series. One end (R4-1) of the resistor (R4) of the sensing resistor part 500 may be connected in series to the first switching element (Q1) of the AC generation switching part 100 and the other end (R4-2) of the resistor (R4) may be connected to one end (R5-1) of the other resistor (R5). The other end (R5-2) of the resistor (R5) of the sensing resistor part 500 may be connected to the negative terminal (1N) of the battery module 1 and connected to the ground (GND).

The switching control part 300 may measure the voltage of the opposite ends (i.e., across the terminals) of the entire sensing resistor part 500 to determine whether the AC signal generated by the switching operation of the AC generation switching part 100 corresponds to the frequency for electrochemical impedance spectroscopy (EIS) measurement. Based on this determination, the switching control part 300 may control the on/off cycle of the AC generation switching part 100 to maintain the determined AC frequency for electrochemical impedance spectroscopy (EIS) measurement.

FIG. 4 is a diagram illustrating an operation of forming an AC discharge path in the event of disconnection of a main discharge path part in an electrochemical impedance spectroscopy measurement apparatus according to an embodiment of the present disclosure.

Referring to FIG. 4, in order for the EIS measurement part 10 to perform electrochemical impedance spectroscopy (EIS) measurement on each battery cell 1a of the battery module 1, the AC discharge switching part 20 may initiate AC discharge. The switching control part 300 of the AC discharge switching part 20 may generate AC by repeatedly controlling the on/off operation of the first switching element (Q1) of the AC generation switching part 100. Simultaneously, AC discharge of the battery module 1 may be performed. Herein, the EIS measurement part 10 may perform electrochemical impedance spectroscopy (EIS) measurement on each battery cell 1a.

Herein, when AC discharge of the battery module 1 is performed, the discharge path formation part 400 may form an AC discharge path. The main discharge path part 410 of the discharge path formation part 400 may be connected to the node with the highest voltage among the plurality of nodes (N1 to Nn) of the plurality of battery cells 1a and outputs the node voltage, thereby forming the AC discharge path. Herein, the EIS measurement part 10 may perform electrochemical impedance spectroscopy (EIS) measurement on each battery cell 1a.

As such, while the EIS measurement part 10 performs electrochemical impedance spectroscopy (EIS) measurement on each battery cell 1a, when the main discharge path part 410 that is connected to the node with the highest voltage among the plurality of nodes (N1 to Nn) of the plurality of battery cells la gets disconnected, a bypass path may be formed through the operation of the sub-discharge path parts 420 connected to the plurality of remaining nodes, thereby changing the AC discharge path.

For example, referring to FIG. 4, when connection to diode D1 of the main discharge path part that is connected to node N1 with the highest voltage among the plurality of nodes (N1 to Nn) of the plurality of battery cells 1a is disconnected, a sub-discharge path may be formed through either diode D2 or diode D3 of the sub-discharge path part 420, which are respectively connected to the plurality of remaining nodes (N2 and N3) excluding node N1 of the battery cell 1a. FIG. 4 shows that a sub-type AC discharge path (A1) is formed through diode D2 connected to node N2 of the battery cell 1a with the highest voltage among the plurality of nodes (N2 and N3).

Herein, the disconnected battery cell 1a is unable to undergo AC discharge, making electrochemical impedance spectroscopy (EIS) measurement impossible for that cell. However, AC discharge is maintained through the bypass path via the node with the second-highest voltage, so electrochemical impedance spectroscopy (EIS) measurement may be performed on the remaining battery cells 1a.

FIG. 5 is a diagram illustrating an operation of forming an AC discharge path in the event of disconnection of a sub-discharge path part in an electrochemical impedance spectroscopy measurement apparatus according to an embodiment of the present disclosure.

Referring to FIG. 5, the switching control part 300 of the AC discharge switching part 20 may generate AC by repeatedly controlling the on/off operation of the first switching element (Q1) of the AC generation switching part 100. Simultaneously, AC discharge of the battery module 1 may be performed. Herein, the EIS measurement part 10 may perform electrochemical impedance spectroscopy (EIS) measurement on each battery cell 1a.

Herein, when AC discharge of the battery module 1 is performed, the discharge path formation part 400 may form an AC discharge path. The main discharge path part 410 of the discharge path formation part 400 may be connected to the node with the highest voltage among the plurality of nodes (N1 to Nn) of the plurality of battery cells 1a and output the node voltage, thereby forming the AC discharge path. During this process, the EIS measurement part 10 may perform electrochemical impedance spectroscopy (EIS) measurement on each battery cell 1a.

As such, while the EIS measurement part 10 performs electrochemical impedance spectroscopy (EIS) measurement on each battery cell 1a, when the sub-discharge path part 420 is disconnected rather than the main discharge path part 410 connected to the node with the highest voltage among the plurality of nodes (N1 to Nn) of the plurality of battery cells la, the main discharge path part 410 connected to the node with the highest voltage among the plurality of nodes (N1 to Nn) of the plurality of battery cells 1a maintains the main discharge path, thereby maintaining the AC discharge path.

For example, referring to FIG. 5, while the main discharge path is formed through diode D1 of the main discharge path part 410 connected to node N1 with the highest voltage among the plurality of nodes (N1 to Nn) of the plurality of battery cells la, either diode D2 or diode D3 of the sub-discharge path part 420, which are respectively connected to the plurality of remaining nodes (N2 and N3), may be disconnected. FIG. 5 shows that when connection to diode D2 connected to node N2 among the plurality of nodes (N2 and N3) is disconnected, the AC discharge path (A1) is maintained through the main discharge path via diode D1 of the main discharge path part 410.

In this embodiment, despite the disconnection of the node of the battery cell 1a connected to the sub-discharge path part 420, since AC discharge of the battery module 1 is maintained through the main discharge path part 410, the AC discharge switching part 20 may perform electrochemical impedance spectroscopy (EIS) measurement on all the battery cells 1a.

Accordingly, the discharge path formation part 400 according to an embodiment of the present disclosure may immediately respond even when a disconnection occurs in the AC discharge path, and may further improve the durability and stability of the entire circuit of the AC discharge switching part 20.

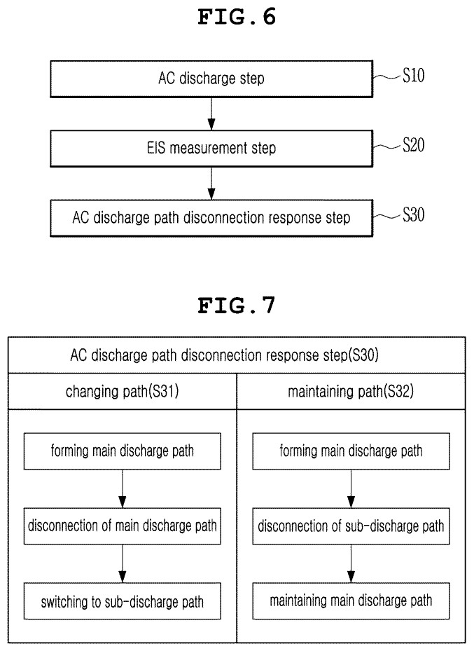

FIG. 6 is a flowchart illustrating each operation of an electrochemical impedance spectroscopy measurement method according to an embodiment of the present disclosure.

Referring to FIG. 6, the electrochemical impedance spectroscopy measurement method according to an embodiment of the present disclosure may include an AC discharge operation S10 (also referred to as AC discharge step) including generating, by the AC discharge switching part 20 connected to the battery module 1 including the plurality of battery cells 1a, AC corresponding to a frequency for electrochemical impedance spectroscopy (EIS) measurement for the battery module 1; performing an EIS measurement operation S20 (also referred to as EIS measurement step), by the EIS measurement part 10 connected to the nodes of the plurality of battery cells 1a included in the battery module 1, electrochemical impedance spectroscopy (EIS) measurement on each of the plurality of battery cells la included in the battery module 1; and performing an AC discharge path disconnection response operation S30 (referred to also as an AC discharge path disconnection response step). Operation S30 includes when one of the plurality of discharge path formation parts that are connected to the plurality of nodes of the plurality of battery cells la becomes disconnected during the electrochemical impedance spectroscopy (EIS) measurement on each of the plurality of battery cells la, responding to the disconnection by forming an AC discharge path through one of the remaining discharge path formation parts in operation S30.

In the battery module 1, the plurality of battery cells la may be electrically connected. In the battery module 1, the plurality of battery cells la may be connected in series, connected in parallel, or connected in a combination of series and parallel.

In generating AC in operation S10, the AC discharge switching part 20 generates AC to form the AC discharge path so that AC discharge of the battery module 1 is performed for the EIS measurement part 10 to perform electrochemical impedance spectroscopy (EIS) measurement.

In operation S20 the EIS measurement part 10 performs electrochemical impedance spectroscopy (EIS) measurement on each battery cell 1a of the battery module 1 as the AC discharge switching part 20 causes AC discharge of the battery module 1.

In the operation of responding to the disconnection of the AC discharge path in operation S30, when one of the AC discharge paths multiplexed by the main discharge path part and the sub-discharge path parts is disconnected, the AC discharge path is formed through the remaining discharge path parts.

In the operation of responding to the disconnection of the AC discharge path in operation S30, the AC discharge path may use a diode as shown in FIG. 2. The AC discharge path may be connected to the nodes (N1 to Nn) of the plurality of battery cells 1a and may operate to output the highest node voltage.

Accordingly, in the embodiments of the present disclosure, the AC discharge switching part 20 always forms the AC discharge path so that AC discharge of the battery module 1 is performed, the EIS measurement part 10 may easily perform electrochemical impedance spectroscopy (EIS) measurement on each battery cell 1a.

FIG. 7 is a diagram illustrating an operation of responding to disconnection of an AC discharge path in an electrochemical impedance spectroscopy measurement method according to an embodiment of the present disclosure.

Referring to FIG. 7, in the electrochemical impedance spectroscopy measurement method according to the present disclosure, in the operation of responding to the disconnection of the AC discharge path in operation S30, when the discharge path formation part connected to the node with the highest voltage among the plurality of nodes of the plurality of battery cells is disconnected, the AC discharge path may be formed through the discharge path formation part connected to the node with the highest voltage among the remaining plurality of discharge path formation parts.

Accordingly, the AC discharge path may be maintained and AC discharge of the battery module 1 is performed, so a state in which electrochemical impedance spectroscopy (EIS) measurement is possible may be maintained.

This may correspond to an AC discharge path change operation S31 shown in FIG. 7. When the main discharge path part 410 that has formed the AC discharge path is disconnected, a bypass path is formed through the sub-discharge path part 420, thereby forming the AC discharge path. This AC discharge path change operation S31 may be seen with FIG. 4.

In addition, in the electrochemical impedance spectroscopy measurement method according to the present disclosure, in the operation of responding to the disconnection of the AC discharge path in operation S30, when one of the plurality of discharge path formation parts connected to the remaining plurality of nodes excluding the node with the highest voltage among the plurality of nodes of the plurality of battery cells is disconnected, the AC discharge path formed through the discharge path formation part connected to the node with the highest voltage may be maintained.

This may correspond to an AC discharge path maintenance operation S32 shown in FIG. 7. When the sub-discharge path part 420 rather than the main discharge path part 410 that has formed the AC discharge path is disconnected, the AC discharge path may be maintained through the main discharge path part 410. This AC discharge path maintenance operation S32 may be seen with FIG. 5.

Accordingly, in an embodiment of the present disclosure, when either the main discharge path part 410 or the sub-discharge path part 420 connected to the nodes of the plurality of battery cells la included in the battery module 1 is disconnected, the AC discharge path may be formed in response to such disconnection. This can prevent a situation in which electrochemical impedance spectroscopy (EIS) measurement for all the battery cells 1a of the battery module 1 becomes impossible.

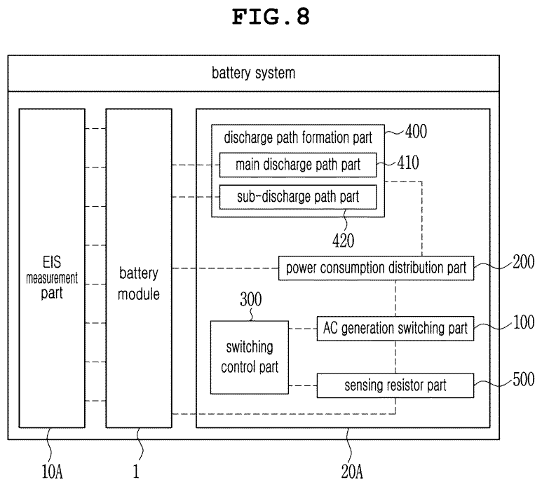

FIG. 8 is a configuration diagram illustrating a battery system according to an embodiment of the present disclosure.

Referring to FIG. 8, the battery system according to an embodiment of the present disclosure may include the battery module 1 including the plurality of battery cells 1a, and an EIS measurement device 10A connected to each of the plurality of battery cells 1a included in the battery module 1. The EIS measurement device 10A is configured to perform electrochemical impedance spectroscopy (EIS) measurement on each of the plurality of battery cells 1a during AC discharge of the battery module 1. The battery system may further include an AC discharge switching device 20A that is connected to the battery module to form an AC discharge path so that AC discharge of the battery module 1 is performed for electrochemical impedance spectroscopy (EIS) measurement in the EIS measurement device 10A. In this embodiment, the AC discharge path is connected to a node with the highest voltage among nodes of the plurality of battery cells 1a.

In the battery module 1, the plurality of battery cells la may be electrically connected. In the battery module 1, the plurality of battery cells la may be connected in series, connected in parallel, or connected in a combination of series and parallel.

The EIS measurement device 10A and the AC discharge switching device 20A have the same configuration and operation as the EIS measurement part 10 and the AC discharge switching part 20 described above with reference to FIGS. 1 to 6. Thus, the technical contents described above may be referenced with FIGS. 1 to 6.

The EIS measurement device 10A may be connected to the nodes (N1 to Nn) of the plurality of battery cells 1a included in the battery module 1 and may perform electrochemical impedance spectroscopy (EIS) measurement on each battery cell 1a. The nodes (N1 to Nn) of the plurality of battery cells 1a may be connection lines that make connections between the battery cells 1a.

The EIS measurement device 10A may be connected to a measurement path protection fuse (PF) for protecting an electrochemical impedance spectroscopy (EIS) measurement path at each connection line connected to the nodes (N1 to Nn) of the plurality of battery cells la included in the battery module 1.

The AC discharge switching device 20A may be electrically connected to the battery module 1, which includes the plurality of battery cells 1a, to form the AC discharge path. The AC discharge path may include a plurality of discharge path formation parts 400 connected to the nodes (N1 to Nn) of the plurality of battery cells 1a. The AC discharge switching part 20 may be connected to the node with the highest voltage among the nodes (N1 to Nn) of the plurality of battery cells 1a through the plurality of discharge path formation parts 400, and may perform AC discharge based on the battery module 1. The node with the highest voltage among the nodes (N1 to Nn) of the plurality of battery cells 1a may be determined based on the negative terminal (1N) of the battery module 1.

In the battery system according to an embodiment of the present disclosure, the AC discharge switching device 20A forms the AC discharge path so that AC discharge of the battery module 1 may be performed, the EIS measurement device 10A may perform electrochemical impedance spectroscopy (EIS) measurement, and the state of the battery module may be diagnosed using this measurement.

In addition, referring to FIG. 8, the AC discharge switching device 20A of the battery system according to an embodiment of the present disclosure may include the AC generation switching part 100 connected in series to the battery module 1 including the plurality of battery cells 1a and including the first switching element (Q1) for generating AC. The AC discharge switching device 20A may also include one or more power consumption distribution parts 200 connected in series to the AC generation switching part 100, and a switching control part 300 configured to control the on/off operation of the AC generation switching part 100 according to a determined frequency for electrochemical impedance spectroscopy (EIS) measurement. The discharge path formation part 400 may be positioned between the battery module 1 and the power consumption distribution part 200, and may be configured to form the AC discharge path. The AC discharge switching device 20A may further include the sensing resistor part 500 positioned between and for connecting the AC generation switching part 100 and the battery module 1 including the plurality of battery cells 1a. The switching control part 300 is configured to control the on/off cycle of the AC generation switching part 100 by measuring the voltage applied to the sensing resistor part 500 to maintain the determined AC frequency for electrochemical impedance spectroscopy (EIS) measurement.

The AC generation switching part 100 may perform a switching operation to generate AC corresponding to the determined frequency for electrochemical impedance spectroscopy (EIS) measurement. The AC generation switching part 100 may be pulse width modulation (PWM) controlled.

The power consumption distribution part 200 may distribute the power consumption that occurs when AC is discharged using the battery module 1 including the plurality of battery cells 1a. The discharge path formation part 400 may include a main discharge path part 410 connected to the node with the highest voltage among the plurality of nodes (N1 to Nn) of the plurality of battery cells 1a; and one or more sub-discharge path parts 420 connected to the remaining nodes excluding the node with the highest voltage among the plurality of nodes (N1 to Nn) of the plurality of battery cells 1a.

The main discharge path part 410 may include a first fuse (F1) and a first diode (MD) connected in series.

The sub-discharge path part 420 may include a second fuse (F2) and a second diode (SD) connected in series.

The discharge path formation part 400 may form the main discharge path by being connected to the node with the highest voltage among the plurality of nodes (N1 to Nn) of the plurality of battery cells 1a through the main discharge path part 410. When the main discharge path is disconnected, a sub-discharge path may be formed through the sub-discharge path part 420. One end of the sensing resistor part 500 may be connected to the negative terminal (1N) of the battery module 1 and the other end thereof may be connected to the AC generation switching part 100. The switching control part 300 may control the on/off cycle of the AC generation switching part 100 by measuring the voltage applied to the sensing resistor part 500 to maintain a determined frequency for electrochemical impedance spectroscopy (EIS) measurement.

The sensing resistor part 500 may include one or more resistance elements to identify AC flowing for electrochemical impedance spectroscopy (EIS) measurement in the form of a voltage. The switching control part 300 may measure the voltage of the opposite ends of the sensing resistor part 500 to determine whether AC generated by the switching operation of the AC generation switching part 100 corresponds to the frequency for electrochemical impedance spectroscopy (EIS) measurement. Through this, the switching control part 300 may control the on/off cycle of the AC generation switching part 100 to maintain the determined AC frequency for electrochemical impedance spectroscopy (EIS) measurement.

Accordingly, in the battery system according to an embodiment the present disclosure, the AC discharge switching device 20A may form the AC discharge path of the battery module 1 required for electrochemical impedance spectroscopy (EIS) measurement by the EIS measurement device 10A. In particular, when either the main discharge path part 410 or the sub-discharge path part 420 connected to the nodes (N1 to Nn) of the plurality of battery cells 1a is disconnected, the AC discharge path may be formed in response to such disconnect. This can prevent a situation in which electrochemical impedance spectroscopy (EIS) measurement becomes impossible.

The embodiments of the present disclosure have been described in detail above through detailed illustrations. The above description is only an example to which the principles of the present disclosure are applied, and other embodiments may be further included or may be substituted without departing from the scope of the present disclosure. Furthermore, the embodiments may be combined to form additional embodiments.

1. An electrochemical impedance spectroscopy measurement apparatus, comprising:
an electrochemical impedance spectroscopy (EIS) measurement part connected to each of a plurality of battery cells included in a battery module, and configured to perform EIS measurement on each of the plurality of battery cells during AC discharge of the battery module; and
an AC discharge switching part connected to the battery module to form an AC discharge path so that AC discharge of the battery module is performed for electrochemical impedance spectroscopy (EIS) measurement in the EIS measurement part, wherein the AC discharge path is connected to a node with the highest voltage among a plurality of nodes of the plurality of battery cells electrically connected.

2. The electrochemical impedance spectroscopy measurement apparatus of claim 1, wherein the AC discharge switching part comprises:
an AC generation switching part electrically connected to the battery module including the plurality of battery cells, and including a first switching element for generating AC;
one or more power consumption distribution parts connected in series to the AC generation switching part;
a switching control part configured to control an on/off operation of the AC generation switching part according to a determined frequency for electrochemical impedance spectroscopy (EIS) measurement; and
a discharge path formation part positioned between the battery module and the power consumption distribution parts for connecting the battery module and the power consumption distribution parts and configured to form the AC discharge path.

3. The electrochemical impedance spectroscopy measurement apparatus of claim 2, wherein the discharge path formation part comprises:
a main discharge path part connected to the node with the highest voltage among the plurality of nodes of the plurality of battery cells; and
one or more sub-discharge path parts connected to the remaining nodes excluding the node with the highest voltage among the plurality of nodes of the plurality of battery cells.

4. The electrochemical impedance spectroscopy measurement apparatus of claim 3, wherein the main discharge path part comprises a first fuse and a first diode connected in series, and
the sub-discharge path part comprises a second fuse and a second diode connected in series.

5. The electrochemical impedance spectroscopy measurement apparatus of claim 2, wherein the power consumption distribution part comprises:
a second switching element of which a drain terminal is connected in series to an output terminal of the discharge path formation part;
a resistance element of which one end is connected to one of the plurality of battery cells and of which the other end is connected to a gate terminal of the second switching element; and
a semiconductor device of which an input terminal is connected to a source terminal of the second switching element and of which an output terminal is connected to the gate terminal of the second switching element, and configured to induce a constant voltage output,
wherein the power consumption distribution part is configured to maintain the second switching element continuously in a turned-on state by causing a voltage at the gate terminal of the second switching element to be maintained higher than a voltage at the source terminal and to be output at a voltage equal to or higher than a breakdown voltage of the semiconductor device.

6. The electrochemical impedance spectroscopy measurement apparatus of claim 5, wherein the second switching element is a field effect transistor, and the semiconductor device is a Zener diode.

7. The electrochemical impedance spectroscopy measurement apparatus of claim 2, wherein the AC discharge switching part further comprises:
a sensing resistor part positioned between the AC generation switching part and the battery module including the plurality of battery cells and for connecting the AC generation switching part and the battery module,
wherein the switching control part is configured to control an on/off cycle of the AC generation switching part by measuring a voltage applied to the sensing resistor part to maintain a determined AC frequency for electrochemical impedance spectroscopy (EIS) measurement.

8. The electrochemical impedance spectroscopy measurement apparatus of claim 7, wherein the sensing resistor part comprises one or more resistance elements.

9. The electrochemical impedance spectroscopy measurement apparatus of claim 1, wherein the EIS measurement part is connected to a measurement path protection fuse for protecting an electrochemical impedance spectroscopy (EIS) measurement path at each connection to the nodes of the plurality of battery cells included in the battery module.

10-11. (canceled)

12. The electrochemical impedance spectroscopy measurement apparatus of claim 2, wherein in responding to the disconnection of the AC discharge path, when the discharge path formation part connected to a node with the highest voltage among the plurality of nodes of the plurality of battery cells is disconnected, the AC discharge path is formed through the discharge path formation part connected to a node with the highest voltage among the remaining plurality of discharge path formation parts, and wherein in responding to the disconnection of the AC discharge path, when one of the plurality of discharge path formation pars connected to the remaining plurality of nodes excluding a node with the highest voltage among the plurality of nodes of the plurality of battery cells is disconnected, the AC discharge path formed through the discharge path formation part connected to the node with the highest voltage is maintained.

13-15. (canceled)
